(19) United States
(12) Patent Application Publication
(10) Pub. No.: US 2006/0108681 A1
(43) Pub. Date: May 25, 2006

(54) Semiconductor component package

(76) Inventors: Kok Hua Chua, Singapore (SG); Adesoji Dairo, Macungie, PA (US); Michael Diberardino, North Wales, PA (US); Ebyson Thomas, Schwenkulle, PA (US); Jeffrey A. Weiss, Allentown, PA (US); Zhengpeng Xiong, Singapore (SG)

Correspondence Address: Lester H. Birnbaum, 2159 Greenmeadow Drive, Macungie, PA, 18062, US

(21) Appl. No.: 11/088,046

(22) Filed: Mar. 23, 2005

Related U.S. Application Data
(60) Provisional application No. 60/630,442, filed on Nov. 23, 2004.

(51) Int. Cl. H01L 23/10

(52) U.S. Cl. 257/720

(57) ABSTRACT

A semiconductor component package and method of fabrication are disclosed. The package employs a heat dissipating element embedded within the protective material over the component. The heat dissipating element is preferably made by stamping, and is formed from an essentially uniform thickness heat conducting sheet. The element is formed so as to have two portions of different heights, the portion with the smaller height overlying but not touching the semiconductor component or wires connecting the semiconductor component.

### CROSS REFERENCE TO RELATED APPLICATION

This application claims the benefit of co-pending provisional patent application No. 60/630442, filed Nov. 23, 2004.

### FIELD OF THE INVENTION

The present invention relates generally to semiconductor devices and, more particularly, to an improved package including such devices.

### BACKGROUND OF THE INVENTION

An important part of Integrated Circuit (IC) technology is the packaging of the semiconductor component. One consideration in the proper functioning of the component is to provide adequate heat dissipation away from the component during operation. Another consideration is to provide protection of the component in the form of some type of encapsulant. For example, one type of package, known in the art as a Heat Slug Plastic Ball Grid Array (PBGAH), includes a copper heat slug embedded within an Epoxy Molding Compound (EMC) which protects the IC component.

It is desirable in such packages to fabricate the heat slug by stamping, which is a highly economical process. It is also desirable to place the heat slug as close as possible to the component for maximum heat dissipation. One design utilizes a heat slug with a uniform height and thickness over the IC component. (See, e.g., U.S. Pat. No. 6,191,360 issued to Tao et al.) Since the component is typically electrically connected to the substrate by wire bonding, increasing the thickness of the slug to get it closer to the component could result in electrically shorting the wires due to contact with the heat slug. In another design, the slug is brought closer to the component by means of a protruded portion over the IC. One disadvantage of such a design is that the slug no longer has a uniform thickness, and cannot be made by stamping. A still further design includes a protruded portion with a uniform thickness which makes direct physical contact with the IC component. (See, e.g., U.S. Pat. No. 6,229,702 issued to Tao et al.) In this design it is important not to apply too much pressure to the heat slug, otherwise the IC component could be damaged. It is therefore important to reduce the height of the heat slug, otherwise the clamp used in the molding process could damage the IC component. However, the reduced height increases the chance of shorting with the wires connected to the substrate, and also allows the EMC layer to be formed over the heat slug reducing the heat dissipation. To avoid these problems, the heat slug thickness is usually reduced, but this lessens the ability of the heat slug to dissipate, heat.

It is desirable, therefore, to provide a semiconductor package which includes a heat dissipating element embedded within a protective layer, where the element has a uniform thickness so that it can be formed by stamping, and where the element does not physically contact the semiconductor component.

### SUMMARY OF THE INVENTION

To achieve these and other objects, and in view of its purposes, the present invention in one aspect, provides a semiconductor component package which includes a semiconductor component, such as an integrated circuit, mounted on a substrate, a protective material formed over the semiconductor component, and a heat dissipating element embedded within the protective material. The heat dissipating element comprises a heat conducting sheet having an essentially uniform thickness with a first portion having a first height. The heat dissipating element also includes a second portion having a second height which is less than the first height. The second portion lies over at least a part of the semiconductor component, but does not make physical contact thereto.

In accordance with a second aspect, the invention is a method of fabricating a semiconductor component package which includes the steps of mounting a semiconductor component, such as an integrated circuit, over a substrate. A heat dissipating element is formed from a heat conducting sheet with an essentially uniform thickness having a first portion with a first height and a second portion with a second height which is less than the first height. The heat dissipating element is mounted over the substrate so that the second portion is over at least a part of the semiconductor component but does not make physical contact therewith. A protective layer is formed over the component and heat dissipating element.

It is to be understood that both the foregoing general description and the following detailed description are exemplary, but are not restrictive, of the invention.

### BRIEF DESCRIPTION OF THE DRAWING

The invention is best understood from the following detailed description when read in connection with the accompanying drawing. It is emphasized that, according to common practice in the semiconductor industry, the various features of the drawing are not to scale. On the contrary, the dimensions of the various features are arbitrarily expanded or reduced for clarity. Included in the drawing are the following figures:

FIG. 1 is a cross sectional view of a semiconductor component package in accordance with an embodiment of the invention; and

FIG. 2 is a top view of an element of the semiconductor component package in accordance with the same embodiment.

### DETAILED DESCRIPTION OF THE INVENTION

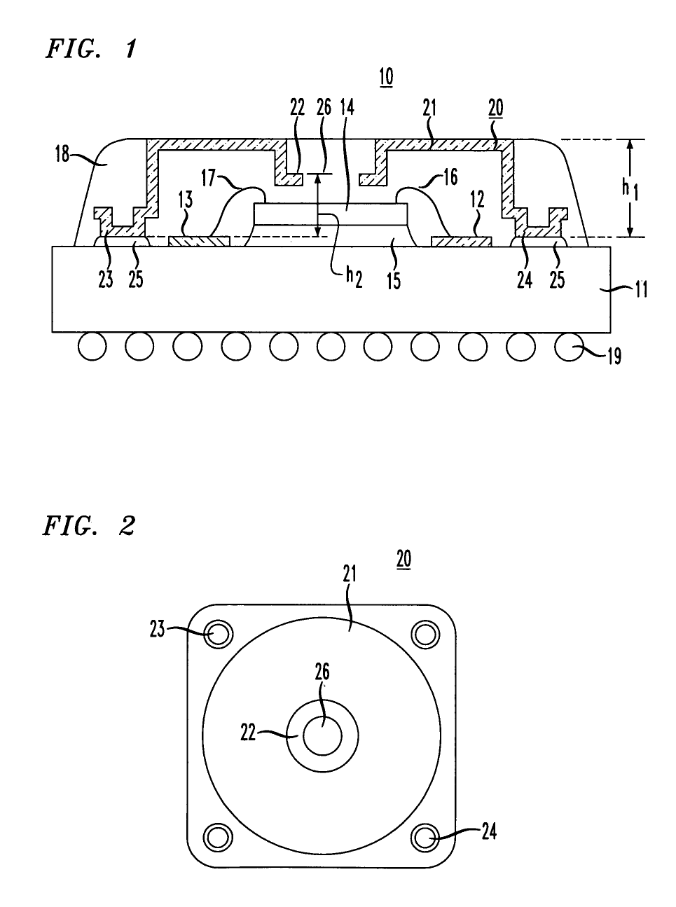

Referring now to the drawing, wherein like reference numerals refer to like elements throughout, FIG. 1 is a cross sectional view of a typical embodiment of a package, 10, including features of the invention. The package includes a substrate, 11, which is typically a ceramic, semiconductor or plastic laminated material. The substrate also usually includes alternate layers of dielectric and conductive layers, as well as planarization layers, which are not shown for the sake of clarity in the illustration (with the exception of conductive traces, 12 and 13, discussed below). In the context of this application, the “substrate” is intended to include all such layers that are formed over the ceramic, semiconductor or plastic laminated material. A semiconductor component, 14, in this example, a standard Integrated Circuit (IC) is mounted over the substrate, 11, using a standard adhesive layer, 15. Electrical connection between the IC and conductive traces, 12 and 13, on the substrate is provided by wires, 16 and 17, respectively, using standard wire bonding techniques. A heat dissipating element, 20, discussed in more detail below, is mounted over the substrate, 11, and over the IC, 14. The IC, 14, wires, 16 and 17, and heat dissipating element, 20, are all embedded within a protective material layer, 18, which in this example, is an Epoxy Molding Compound (EMC) such as a mixture of multifunctional epoxy, filler, hardener, and pigment. The package can be mounted to another substrate (not shown) by means of solder balls, e.g., 19, in accordance with standard ball grid array packaging technology.

The heat dissipating element, 20, is formed from a metal sheet which in this example is copper, but could be any metal or other material capable of conducting heat away from the IC, 14. Since the element, 20, has an essentially uniform thickness, it can be formed by standard stamping techniques. In this example, the thickness is 0.3 mm, but thicknesses in the range 0.1 mm to 0.5 mm are generally useful. The element, 20, is shaped to include a first portion, 21, which has a height, h₁, and a second portion, 22, which has a height h₂. It will be noted that h₂ is less than h₁, and that the second portion, 22, preferably lies as much as possible over the IC component, 14, for wire bonded packages without touching the wires 16 and 17, while the first portion, 21, lies primarily over the area of the substrate not including the IC component. It will also be noted that the second portion, 22, is close to but does not touch the IC component. Preferably, the second portion will lie a distance from the component, 14, which is in the range 0.1 mm to 0.42 mm. The element, 20, is mounted to the substrate, 11, by applying an adhesive, 25, to the feet, e.g, 23 and 24, of the element, 20, and contacting the feet to the substrate. The feet are typically bumps which are stamped in the element so that the protective material can flow underneath the element during the encapsulation process, but are not essential to the invention. (It will also be noted that h₁ and h₂ are measured from the bottom of the feet to the top surfaces of their respective portions, 21 and 22.)

It will be noted that the height, h₁, of the first portion, 21, is chosen to provide sufficient clearance of the heat dissipating element, 20, from the wires, 16 and 17, so that no shorting will occur. In this example, the height, h₁, was 1.17 mm, but heights in the range 1.17 mm to 1.22 mm are recommended. The height, h₂, was chosen to bring the heat dissipating element, 20, as close as possible to the semiconductor component, 14, without making contact therewith, so that the element, 20, can conduct heat away from the component efficiently without damaging the component. In this example, the height, h₂, was 0.8 mm, but heights in the range 0.55 mm to 0.87 mm are generally useful depending on the thickness of the semiconductor component, 14. In general, the difference between h₁ and h₂ will be in the range 0.3 mm to 0.62 mm.

Subsequent to the mounting of the heat dissipating element, 20, to the substrate, 11, the protective layer, 18, is formed over the substrate, semiconductor component, and heat dissipating element. Any standard deposition technique can be employed. It is preferred, when using an epoxy molding compound, to deposit by a transfer molding process. Since the material can flow in the horizontal and vertical directions, it is preferred to include a hole, 26, in the portion, 22, of the heat dissipating element to facilitate the flow of the material over the semiconductor component, 14. (See also the top view of element, 20, illustrated in FIG. 2.) In this example, the hole was circular, but could be any shape. It is preferred to deposit the protective material, 18, so that the top surface of portion 21 is exposed to the environment. Since the protective material is a relatively poor heat conductor, the exposure of the top surface of the portion 21 ensures that most of the heat from the semiconductor element, 14, will be carried from the portion 22, to the portion 21 and into the air. Of course, a thin layer of the protective material over the top surface could be used, but would not be as efficient. It is desirable that there be no more than 0.15 mm of the protective material over the portion 21.

Although the invention has been described with reference to exemplary embodiments, it is not limited to those embodiments. For example, while the portion 22 is shown only over the IC component, 14, it could extend outside the area above the component for components that are not contacted by wire bonding. Rather, the appended claims should be construed to include other variants and embodiments of the invention which may be made by those skilled in the art without departing from the true spirit and scope of the present invention.

What is claimed:

1. A semiconductor component package comprising:
a semiconductor component mounted on a substrate;
a protective material formed over the semiconductor component; and
a heat dissipating element embedded within the protective material, the heat dissipating element comprising a heat conducting sheet having an essentially uniform thickness with a first portion having a first height and a second portion having a second height which is less than the first height, the second portion lying over at least a part of the semiconductor component, but not making physical contact thereto.

2. The package according to claim 2 wherein the heat dissipating element further includes a hole through the sheet in the second portion.

3. The package according to claim 1 wherein the second portion is placed a distance from the component in the range 0.1 to 0.42 mm.

4. The package according to claim 1 wherein the sheet has a thickness in the range 0.1 mm to 0.5 mm.

5. The package according to claim 1 wherein the first portion has a top surface that is not covered by the protective material.

6. The package according to claim 1 wherein the sheet comprises a metal.

7. The package according to claim 1 wherein the difference between the first and second heights is within the range 0.3 mm to 0.62 mm.

8. The package according to claim 1 wherein the protective material is an epoxy molding compound.

9. The package according to claim 1 wherein electrical contact to the semiconductor component is provided by wires connected to conductive traces on the substrate, and the second portion overlies only an area above the component.

10. A method of forming a semiconductor component package comprising the steps of:
mounting a semiconductor component over a substrate;
forming a heat dissipating element, the element comprising a heat conducting sheet with an essentially uniform thickness having a first portion with a first height and a second portion with a second height which is less than the first height;
mounting the heat dissipating element over the substrate so that the second portion is over at least a part of the semiconductor component but does not make physical contact therewith; and
forming a protective layer over the component and heat dissipating element.

11. The method according to claim 10 wherein a hole is formed through the second portion of the heat dissipating element so that the protective layer can flow therethrough during forming.

12. The method according to claim 10 wherein the second portion is placed a distance from the component in the range 0.1 to 0.42 mm.

13. The method according to claim 10 wherein the sheet has a thickness in the range 0.1 mm to 0.5 mm.

14. The method according to claim 10 wherein the first portion has a top surface and the protective material is formed so as not to cover the top surface.

15. The method according to claim 10 wherein the sheet comprises a metal.

16. The method according to claim 10 wherein the difference between the first and second heights is within the range 0.3 mm to 0.62 mm.

17. The method according to claim 10 wherein the protective material is an epoxy molding compound.

18. The method according to claim 10 wherein electrical contact to the semiconductor component is provided by wires connected to conductive traces on the substrate, and the second portion overlies only an area above the component.

19. The method according to claim 10 wherein the heat dissipating element is formed by stamping.
